(19) United States
(12) Patent Application Publication
(10) Pub. No.: US 2020/0144433 A1
(43) Pub. Date: May 7, 2020

(54) PHOTOVOLTAIC DEVICE

(71) Applicant: UNIVERSITY OF OTTAWA, Ottawa (CA)

(72) Inventors: Christopher E. VALDIVIA, Ottawa (CA); Karin HINZER, Ottawa (CA)

(73) Assignee: UNIVERSITY OF OTTAWA, Ottawa, ON (CA)

(21) Appl. No.: 16/625,174

(22) PCT Filed: Jun. 22, 2018
(86) PCT No.: PCT/CA2018/050767

§ 371 Date: Dec. 20, 2019

Related U.S. Application Data
(60) Provisional application No. 62/622,198, filed on Jan. 26, 2018.
(60) Provisional application No. 62/523,985, filed on Jun. 23, 2017.

(51) Int. Cl. H01L 31/05; H01L 31/043; H01L 31/0735; H01L 31/18

(52) U.S. Cl. CPC H01L 31/0508; H01L 31/1844; H01L 31/0735; H01L 31/043

(57) ABSTRACT

A photovoltaic device comprises at least two sub-cells, at least one connecting element electrically connecting adjacent sub-cells to one another, each sub-cell comprising:

at least one segment; and at least one connecting element electrically connecting adjacent segments to one another in the event that a sub-cell has more than one segment; each one of the sub-cells having a unique bandgap and being arranged such that bandgaps of the sub-cells are in descending order with respect to a light incident surface of the photovoltaic device, each sub-cell being designed such that all segments of the photovoltaic device produce approximately the same current.

### CROSS-REFERENCE TO RELATED APPLICATIONS

This application claims the benefit of U.S. Provisional Patent Application No. 62/523,985, filed on Jun. 23, 2017 and U.S. Provisional Patent Application No. 62/622,198, filed on Jan. 26, 2018 the entireties of which are incorporated herein by reference.

### FIELD

This application relates to photovoltaic devices.

### BACKGROUND

Photovoltaic devices respond to optical power by generating a voltage across its terminals which can give rise to an electric current in an external circuit. In this way, the optical power is converted into useful electric power.

The total output power P_{device} of a photovoltaic device is calculated according to equation 1:

P_{device}=I_{device}V_{device} [1]

where I_{device} is the current of the photovoltaic device, V_{device} is the voltage of the photovoltaic device. The current of the photovoltaic device I_{device} is limited by the minimum value of current flowing through any segment therein. As the total output power P_{device} is proportional to the current of the photovoltaic device I_{device}, the overall efficiency of the photovoltaic device is increased by ensuring the same current flows through each segment of the photovoltaic device.

Similarly, the maximum output power Pₘₐₓ of the photovoltaic device is calculated according to equation 2:

Pₘₐₓ=FF I_{sc}V_{oc} [2]

where FF is the fill factor of the photovoltaic device, I_{sc} is the short-circuit current of the photovoltaic device and V_{oc} is the open-circuit voltage of the photovoltaic device. The short-circuit current of the photovoltaic device I_{sc} is also limited by the minimum value of current flowing through any segment therein. As the maximum output power Pₘₐₓ is proportional to the short-circuit current of the photovoltaic device I_{sc}, the overall efficiency of the photovoltaic device is maximized by ensuring the same current flows through each segment of the photovoltaic device.

Further, if any segment of sub-cell of a photovoltaic device generates excess current, this current cannot flow through the rest of the device and thus recombines, contributing to heating of the photovoltaic device, which is detrimental to performance, wastes energy and reduces the overall efficiency of the photovoltaic device.

Although photovoltaic devices have been considered, improvements are desired. It is therefore an object at least to provide a novel photovoltaic device.

### SUMMARY

It should be appreciated that this Summary is provided to introduce a selection of concepts in a simplified form that are further described below in the Detailed Description.

This Summary is not intended to be used to limit the scope of the claimed subject matter.

Accordingly, in one aspect there is provided a photovoltaic device comprising at least two sub-cells, at least one connecting element electrically connecting adjacent sub-cells to one another, each sub-cell comprising at least one segment, and at least one connecting element electrically connecting adjacent segments to one another in the event that a sub-cell has more than one segment, each one of the sub-cells having a unique bandgap and being arranged such that bandgaps of the sub-cells are in descending order with respect to a light incident surface of the photovoltaic device, each sub-cell being designed such that all segments of the photovoltaic device produce approximately the same current.

In an embodiment, each segment comprises at least one emitter and base. The emitter is one of p-doped and n-doped and the base is the other of p-doped and n-doped.

In an embodiment, a first sub-cell comprises four segments. A second sub-cell comprises three segments.

In an embodiment, one of the sub-cells is made of indium gallium phosphide (InGaP) and has a bandgap of approximately 1.8 eV. One of the sub-cells is made of gallium arsenide (GaAs) and has a bandgap of approximately 1.4 eV.

In an embodiment, the at least one connecting element electrically connecting adjacent sub-cells to one another is made of a material substantially transparent to light being absorbed by a lower of the adjacent sub-cells with respect to the light incident surface.

In an embodiment, the photovoltaic device further comprises a layer configured to extract current and voltage from the photovoltaic device.

In an embodiment, the at least one connecting element electrically connecting adjacent segments to one another comprises at least one highly n-doped layer and at least one highly p-doped layer.

In an embodiment, the at least one connecting element electrically connecting adjacent sub-cells to one another is a tunnel junction.

In an embodiment, the at least one connecting element electrically connecting adjacent segments to one another is a tunnel junction.

In an embodiment, the photovoltaic device is a solar cell.

In an embodiment, the photovoltaic device is formed by epitaxial growth in a single monolithic stack.

In an embodiment, the photovoltaic device is composed of a wafer-bonded stack of two or more sub-devices, each separately formed by epitaxial growth in a monolithic stack.

In an embodiment, the photovoltaic device is composed of a mechanical stack of two or more sub-devices, each separately formed by at least one of epitaxial growth in a monolithic stack and wafer bonding.

### BRIEF DESCRIPTION OF THE DRAWINGS

Embodiments will now be described more fully with reference to the accompanying drawings in which:

FIG. 1 shows an embodiment of a photovoltaic device;

FIG. 2 shows an exemplary segment forming part of the photovoltaic device;

FIG. 3 shows an exemplary tunnel junction forming part of the photovoltaic device of FIG. 1;

FIG. 4 is a band diagram showing energy across each segment of the photovoltaic device of FIG. 1;

FIG. 5A is a graph of solar-to-electrical conversion efficiencies of a “Standard MJ” case;

FIG. 5B is a graph of solar-to-electrical conversion efficiencies of a “Segmented MJ” case with an identical range of subcell bandgaps;

FIG. 5C is a graph of solar-to-electrical conversion efficiencies of a “Standard MJ” case with added series resistance of Rₛ=15 m Ω cm²;

FIG. 5D is a graph of solar-to-electrical conversion efficiencies of a “Segmented MJ” case with added series resistance of Rₛ=15 m Ω cm²;

FIG. 6 is a graph of current-balance figure-of-merit for the “Segmented MJ” case for each combination of subcells;

FIGS. 7A to 7C are graphs of the number of segments in each optimized subcell of FIGS. 5B, 5D and 6, respectively;

FIG. 8A is a graph of solar-to-electrical conversion efficiencies of a “Standard InP MJ” case;

FIG. 8B is a graph of solar-to-electrical conversion efficiencies of a “Segmented InP MJ” case with an identical range of subcell bandgaps;

FIG. 8C is a graph of solar-to-electrical conversion efficiencies of a “Standard InP MJ” case with added series resistance of Rₛ=15 m Ω cm²;

FIG. 8D is a graph of solar-to-electrical conversion efficiencies of a “Segmented InP MJ” case with added series resistance of Rₛ=15 m Ω cm²;

FIG. 9A is a graph of solar-to-electrical conversion efficiencies of a “Standard Ge MJ” case;

FIG. 9B is a graph of solar-to-electrical conversion efficiencies of a “Segmented Ge MJ” case with an identical range of subcell bandgaps;

FIG. 9C is a graph of solar-to-electrical conversion efficiencies of a “Standard Ge MJ” case with added series resistance of Rₛ=1 Ω cm²; and

FIG. 9D is a graph of solar-to-electrical conversion efficiencies of a “Segmented Ge MJ” case with added series resistance of Rₛ=1 Ω cm².

### DETAILED DESCRIPTION OF THE EMBODIMENTS

The foregoing summary, as well as the following detailed description of certain examples will be better understood when read in conjunction with the appended drawings. As used herein, an element or feature introduced in the singular and preceded by the word “a” or “an” should be understood as not necessarily excluding the plural of the elements or features. Further, references to “one example” or “one embodiment” are not intended to be interpreted as excluding the existence of additional examples or embodiments that also incorporate the described elements or features. Moreover, unless explicitly stated to the contrary, examples or embodiments “comprising” or “having” or “including” an element or feature or a plurality of elements or features having a particular property may include additional elements or features not having that property. Also, it will be appreciated that the terms “comprises”, “has”, “includes” means “including but not limited to” and the terms “comprising”, “having” and “including” have equivalent meanings.

As used herein, the term “and/or” can include any and all combinations of one or more of the associated listed elements or features.

It will be understood that when an element or feature is referred to as being “on”, “attached” to, “connected” to, “coupled” with, “contacting”, etc. another element or feature, that element or feature can be directly on, attached to, connected to, coupled with or contacting the other element or feature or intervening elements may also be present. In contrast, when an element or feature is referred to as being, for example, “directly on”, “directly attached” to, “directly connected” to, “directly coupled” with or “directly contacting” another element of feature, there are no intervening elements or features present.

It will be understood that spatially relative terms, such as “under”, “below”, “lower”, “over”, “above”, “upper”, “front”, “back” and the like, may be used herein for ease of description to describe the relationship of an element or feature to another element or feature as illustrated in the figures. The spatially relative terms can however, encompass different orientations in use or operation in addition to the orientation depicted in the figures.

In the following, a photovoltaic device is described and is used to convert broadband optical power into electrical power. The photovoltaic device comprises at least two sub-cells. At least one connecting element in the form of a tunnel junction electrically connects adjacent sub-cells to one another. Each sub-cell comprises at least one segment.

In the case that a sub-cell comprises more than one segment, a connecting element in the form of a tunnel junction is used to electrically connect adjacent segments to one another. Each sub-cell has a unique bandgap. The photovoltaic device is arranged such that the bandgaps are in descending order with respect to a light incident surface thereof. Each sub-cell is designed such that all segments of the photovoltaic device produce a same current.

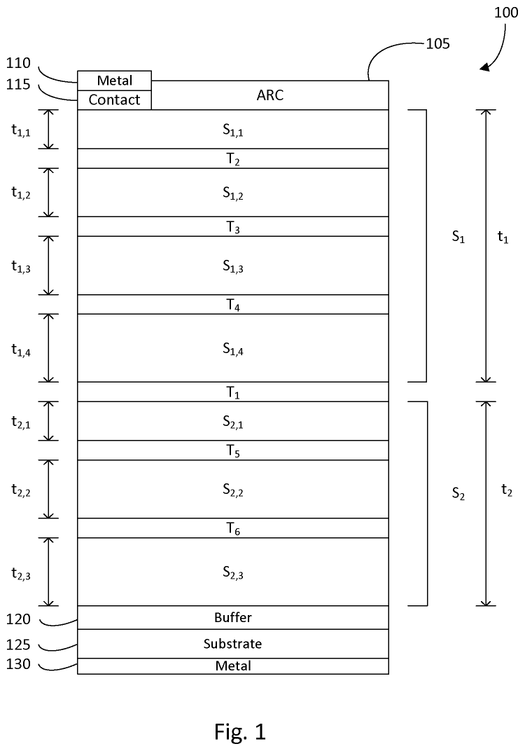

Turning now to FIG. 1, a photovoltaic device is shown and is generally identified by reference numeral 100. In this embodiment, the photovoltaic device 100 is in the form of a solar cell and comprises a light incident surface 105 covered by an antireflection coating (ARC). A metal layer 110 and a contact layer 115 are provided to extract current and voltage generated by the photovoltaic device 100. Positioned below the light incident surface 105 is a first sub-cell S₁ and below that is a second sub-cell S₂. As will be described in more detail below, a connecting element which in this embodiment is a tunnel junction T₁ electrically connects a side of the first sub-cell S₁ to a side of the second sub-cell S₂. A buffer layer 120 is provided below the second sub-cell S₂. The buffer layer 120 is used to provide electrical conductivity (lateral sheet conductivity or vertical conductivity). As will be appreciated, the buffer layer 120 may also initiate a high-quality epitaxial layer and may also provide a barrier for dopant diffusion. A substrate 125 is provided below the buffer layer 120. The substrate 125 provides mechanical support and defines the lattice constant of a semiconductor crystal. A metal layer 130 is provided below the substrate 125.

The first sub-cell S₁ and the second sub-cell S₂ are made of different materials with respect to one another and have different bandgaps. Each sub-cell comprises one or more segments electrically connected in series. The number of segments for each sub-cell is chosen to ensure a current generated by each segment for a sub-cell is generally equal when illuminated by the design spectrum or spectra. Further, the number of segments for each sub-cell is chosen to ensure a current generated by every segment within the photovoltaic device 100 is generally equal or close to equal. As a result, the overall current of the photovoltaic device 100 is maximized thereby maximizing the overall efficiency of the photovoltaic device 100.

In this embodiment, the first sub-cell S₁ comprises four (4) segments S_{1,1}, S_{1,2}, S_{1,3}, and S_{1,4} and three (3) connecting elements in the form of tunnel junctions T₂, T₃ and T₄. Tunnel junction T₂ electrically connects segment S_{1,1} to segment S_{1,2}. Similarly, tunnel junction T₃ electrically connects segment S_{1,2} to segment S_{1,3} and tunnel junction T₄ electrically connects segment S_{1,3} to segment S_{1,4}. Segments S_{1,1}, S_{1,2}, S_{1,3}, and S_{1,4} have respective total thicknesses of t_{1,1}, t_{1,2}, t_{1,3}, and t_{1,4}. The thickness of each segment is chosen to ensure the correct proportion of available photons are absorbed by each segment. As will be appreciated, photons are absorbed exponentially with depth following the material's absorption coefficient. As such, segments of the sub-cell nearer to the light incident surface 105 have a thickness less than subsequent segments within the same sub-cell. In this embodiment, the first sub-cell S₁ is made of indium gallium phosphide (InGaP) and as such each segment S_{1,1}, S_{1,2}, S_{1,3}, and S_{1,4} is made of InGaP. In this embodiment, the first sub-cell Si has a bandgap of 1.8 eV and a thickness t₁ of 1.5 μm.

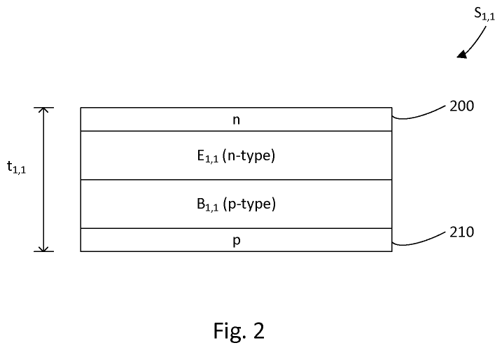

Turning to FIG. 2, segment S_{1,1} is shown. As can be seen, the segment S_{1,1} has a total thickness t_{1,1}. Segment S_{1,1} comprises a front window 200, an emitter layer E_{1,1}, a base layer B_{1,1} and a back window 210. The front window 200 is positioned above the emitter layer E_{1,1} and has the same doping type thereof. In this embodiment, the emitter layer E_{1,1} is n-doped and made of InGaP. As such the front window 200 is also n-doped. The base layer B_{1,1} is positioned below the emitter layer E_{1,1}. In this embodiment, the base layer B_{1,1} is p-doped and is made of InGaP. The emitter layer E_{1,1} and the base layer B_{1,1} together form a p-n junction. The back window 210 is positioned below the base layer B_{1,1} and has the same doping type thereof, which in this embodiment is p-doped. Segments S_{1,2,} S_{1,3,} and S_{1,4} are similar to segment S_{1,1}.

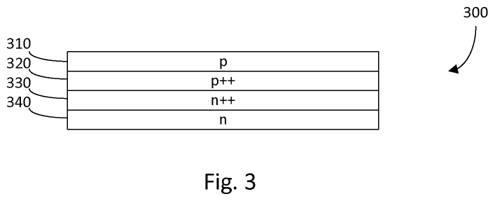

Turning to FIG. 3, tunnel junction T₂ is shown. As can be seen, tunnel junction T₂ comprises a first layer 310 that is p-doped. The first layer 310 is electrically connected to the base layer B_{1,1} of segment S_{1,1}. A second layer 320 is electrically connected to the first layer 310. The second layer 320 is p-doped at a concentration higher than the first layer 310. A third layer 330 is electrically connected to the second layer 320. The third layer 330 is n-doped at a concentration similar to that of the second layer 320. A fourth layer 340 is electrically connected to the third layer 330. The fourth layer 340 is n-doped at a concentration less than the third layer 330 (at a concentration similar to that of the first layer 310). The fourth layer 340 is electrically connected to the segment adjacent to segment S_{1,1}, specifically segment S_{1,2}. In this embodiment, the tunnel junction T₂ is made of the same material as first sub-cell S₁. However it will be appreciated that, in other embodiments, the tunnel junction T₂ may be made of a different material having a bandgap equal to or greater than that of the first sub-cell S₁. In another embodiment, the tunnel junction T₂ may be made of a material having a bandgap less than that of the first sub-cell S₁ and as such may absorb some light. The Tunnel junctions T₃ and T₄ are similar to that of T₁.

As shown in FIG. 1, in this embodiment sub-cell S₂ comprises three (3) segments S_{2,1}, S_{2,2} and S_{2,3,} and two (2) connecting elements in the form of tunnel junctions T₅ and T₆. Segments S_{2,1}, S_{2,2} and S_{2,3} are similar to that shown in FIG. 2 and tunnel junctions T₅ and T₆ are similar to that shown in FIG. 3. Tunnel junction T₅ electrically connects segment S_{2,1} to segment S_{2,2}. Similarly, tunnel junction T₆ electrically connects segment S_{2,2} to segment S_{2,3}. Segments S_{2,1}, S_{2,2} and S_{2,3} have respective total thicknesses of t_{2,1}, t_{2,2} and t_{2,3}. In this embodiment, the second sub-cell S₂ is made of gallium arsenide (GaAs) and as such each segment S_{2,1}, S_{2,2} and S_{2,3}, is made of GaAs. In this embodiment, the second sub-cell S₂ has a bandgap of 1.4 eV and a thickness t₂ of 4 μm.

The first sub-cell S₁ has a bandgap greater than that of the second sub-cell S₂. As such, the first sub-cell S₁ must be positioned nearer the light incident surface 105 than the second sub-cell S₂. As mentioned previously, tunnel junction T₁ electrically connects the first sub-cell S₁ to the second sub-cell S₂. In this embodiment, the tunnel junction T₁ is similar to that shown in FIG. 3 and is made of a material that is sufficiently transparent to light being absorbed by the second sub-cell S₂. Put another way, in this embodiment the tunnel junction T₁ is made of a material having a bandgap equal to or greater than the sub-cell above it, which in this embodiment is the first sub-cell S₁. However it will be appreciated that, in other embodiments, the tunnel junction T₁ may be made of a material having a bandgap equal to or less than that of the sub-cell above it.

As mentioned previously the photovoltaic device current is equal to the minimum current through any one of the segments. As such, the number of segments in each sub-cell is specifically chosen to ensure that the current flowing through each segment of the entire photovoltaic device 100 is generally equal. An example is shown in Table 1:

TABLE 1

| | Nominal | Number of | | Nominal | |
|---|---|---|---|---|---|
| | Sub-cell | Segments | Segment | Sub-cell | Segment |
| Sub-cell | Current | Nₘ | Current | Voltage | Voltage |
| S₁ | 12 mA/cm² | 4 | 3 mA/cm² | 1.4 V | 1.4 V |
| S₂ | 9 mA/cm² | 3 | 3 mA/cm² | 1.0 V | 1.0 V |

As can be seen in Table 1, the current flowing through each segment of photovoltaic device 100 is equal to 3 mA/cm². Since each segment has the same current, the current of the photovoltaic device I_{device} is equal to 3 mA/cm². In this embodiment, the segments are optimized for current balance at the short-circuit current.

As will be appreciated, in Table 1 the nominal sub-cell voltage is set according to the bandgap-voltage offset as calculated in equation 3:

$${W}_{oc} = \frac{{E}_{g}}{q} - {V}_{oc} = 0.4 V \qquad [ 3 ]$$

where E_{g} is the bandgap and q is the electronic charge.

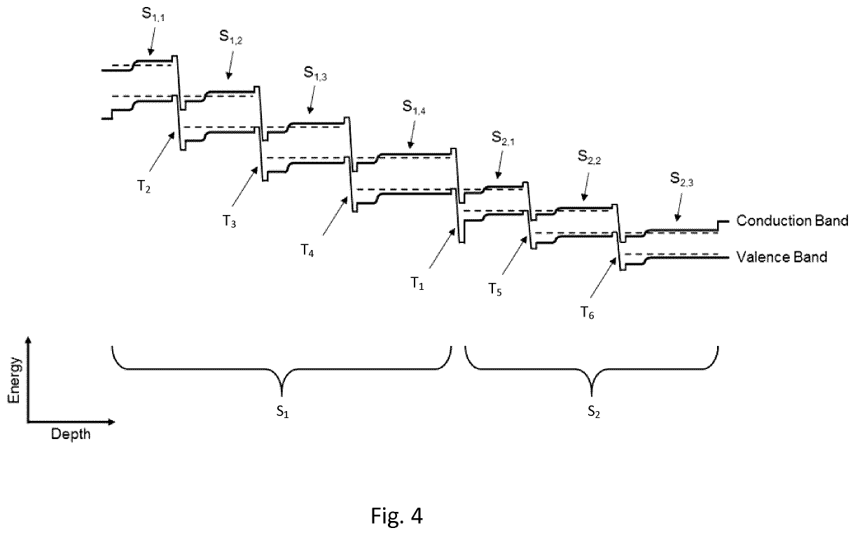

A band diagram showing the energy vs. depth of each segment S_{1,1}, S_{1,2} . . . S_{2,3} of the photovoltaic device 100 is shown in FIG. 4. As can be seen, segments S_{1,1}, S_{1,2}, S_{1,3}, and S_{1,4} have similar segment voltages and segments S_{2,1}, S_{2,2} and S_{2,3} have similar segment voltages. The voltage V_{device} of the photovoltaic device 100 is a sum of the voltage produced by each sub-cell. As an approximation, the voltage V_{device} is equal to the open circuit voltage V_{oc} and is calculated according to equation 4:

V_{device}=Vₛ₁N₁Vₛ₂N₂=1.4V*4+1.0V*3=8.6V [4]

The maximum output power of the device Pₘₐₓ is calculated using equation 2 (defined above), assuming a fill factor of 85%:

$${P}_{max} = 85 \% * 8.6 V * 3 \frac{mA}{{cm}^{2}} = 21.9 \frac{mW}{{cm}^{2}}$$

As the maximum output power Pₘₐₓ of the photovoltaic device 100 is proportional to the short-circuit current of the photovoltaic device I_{sc}, the overall efficiency of the photovoltaic device 100 is increased by ensuring the same current flows through each segment of the photovoltaic device.

As will be appreciated, the photovoltaic device may convert broadband optical power such as for example a terrestrial solar spectrum (impacted by air mass, water vapor, ozone, aerosols, particulates, etc.), extraterrestrial solar spectrum, spectrum available on another heavenly body impacted by local atmospheric conditions, where present, or artificial spectrum such as for example indoor lighting.

Those skilled in the art will appreciate that in embodiments the photovoltaic device is formed by epitaxial growth in a single monolithic stack. Alternatives are also available. For example, in another embodiment the photovoltaic device is composed of a wafer-bonded stack of two or more sub-devices, each separately formed by epitaxial growth in a monolithic stack. In another embodiment, the photovoltaic device is composed of a mechanical stack of two or more sub-devices, each separately formed by at least one of epitaxial growth in a monolithic stack and wafer bonding.

Those skilled in the art will appreciate that in embodiments the single monolithic stack is composed entirely of layers that are lattice-matched to a substrate of the photovoltaic device.

Those skilled in the art will appreciate that in embodiments the single monolithic stack comprises at least one layer that is lattice-mismatched to a substrate of the photovoltaic device.

Those skilled in the art will appreciate that in embodiments the photovoltaic device is composed of a wafer-bonded stack of two or more sub-devices, each separately formed by epitaxial growth in a monolithic stack.

Those skilled in the art will appreciate that in embodiments the photovoltaic device is composed of a wafer-bonded stack of two or more sub-devices each separately formed by epitaxial growth in a monolithic stack, wherein at least one of the sub-devices is comprised entirely of layers that are lattice-matched to a substrate of the photovoltaic device and the remaining sub-devices comprise at least one layer that is lattice-mismatched to the substrate.

Those skilled in the art will appreciate that in embodiments the photovoltaic device is composed of a wafer-bonded stack of two or more sub-devices, each separately formed by epitaxial growth in a monolithic stack containing one or more layers that are lattice-mismatched to a substrate of the photovoltaic device.

Those skilled in the art will appreciate that in embodiments the photovoltaic device is composed of mechanical stacking of two or more sub-devices.

Those skilled in the art will appreciate that in embodiments the photovoltaic device is composed of two or more sub-devices stacked via combinations of wafer-bonding and mechanical stacking.

Those skilled in the art will appreciate that in embodiments the photovoltaic device is composed of a mechanical stack of two or more sub-devices, each separately formed by at least one of epitaxial growth in a monolithic stack and wafer bonding.

Those skilled in the art will appreciate that in embodiments the photovoltaic device comprises one or more monolithic stacks formed via one or more thin film deposition techniques selected from a group consisting of thermal evaporation, electron-beam evaporation, sputtering, atomic layer deposition, pulsed laser deposition, cathodic arc deposition, electrodeposition, electrohydrodynamic deposition, sol-gel method, dip coating, spin coating, spraying techniques, chemical vapor deposition, plasma enhanced chemical vapor deposition, metalorganic chemical vapor deposition, plasma enhance chemical vapor deposition, molecular beam epitaxy, and chemical beam epitaxy.

Although the segments are described as being optimized for current balance at the short-circuit current, those skilled in the art will appreciate that alternatives are available.

For example, the segments may be optimized at a maximum power point, or under any other load condition. Further, the segments may be optimized for current balance under any illumination spectrum.

Although the first sub-cell is described as having has a bandgap of 1.8 eV and a thickness of 1.5 μm and the second sub-cell is described as having a bandgap of 1.4 eV and a thickness of 4 μm, those skilled in the art will appreciate that any suitable bandgap or thickness may be used.

Although in embodiments described above the photovoltaic device is described as comprising two sub-cells, a first of which comprises four (4) segments and a second of which comprises 3 (segments), those skilled in the art will appreciate that any number of sub-cells comprising any number of segments may be used. For example, in another embodiment three sub-cells may be used. The first sub-cell comprising four segments, the second sub-cell comprising three segments and the third sub-cell comprising six segments.

Although in embodiments described above the segments are described as being made of indium gallium phosphide (InGaP) and gallium arsenide (GaAs), those skilled in the art will appreciate that other materials may be used. For example, the materials may include III-V, II-VI, and IV materials and compounds of any composition such as for example GaAs, InGaAs, AlGaAs, InGaP, AlInGaP, AIGaP, Ge, SiGeSn, InGaAsP, InGaAsN, InGaAsNSb, AlGaAsN, AlInGaAsN, AlGaAsNSb and AlInGaAsNSb.

Although in embodiments described above each segment is described as being a p-n junction, those skilled in the art will appreciate that alternatives are available. For example, in another embodiment some or all of the p-n junctions may be p-i-n junctions.

Similarly, some or all of the tunnel junctions may be p-i-n junctions.

Those skilled in the art will appreciate that the tunnel junctions described above may include additional sub-layers to control dopant diffusion, dopant species, etc. Further, a thin intrinsic layer may be used between the p-doped and n-doped layer.

Those skilled in the art will appreciate that segments within a sub-cell may have slightly different bandgaps. For example, an ordering effect in InGaP may shift the bandgap from 1.91 eV to 1.76 eV. In this embodiment, the most disordered material (1.91 eV) is positioned on top of other segments with increasing disorder such that the bandgaps of the segments slightly decrease. Alternatively, only the bottom segment may have a slightly smaller bandgap.

Examples will now be described.

### Example 1: Detailed Balance-Based Calculations on Idealized Triple-Junction Solar Cells

Detailed balance-based calculations were performed on idealized triple-junction solar cells, based on the standard design of fully lattice-matched InGaP/InGaAs/Ge subcells.

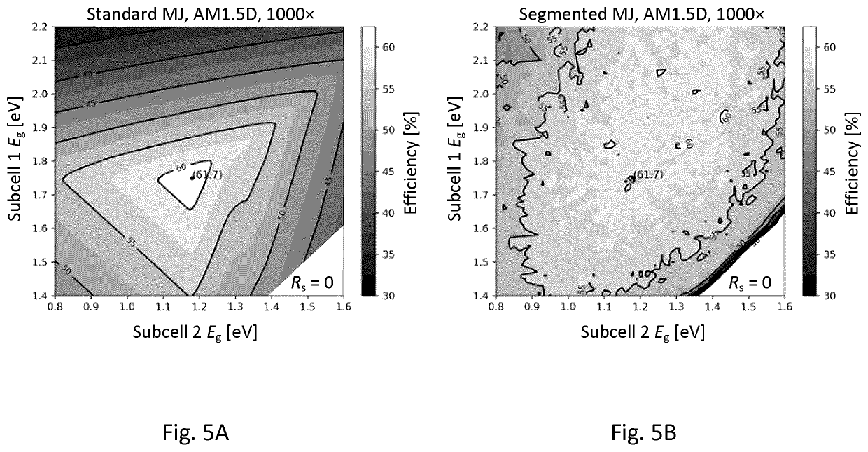

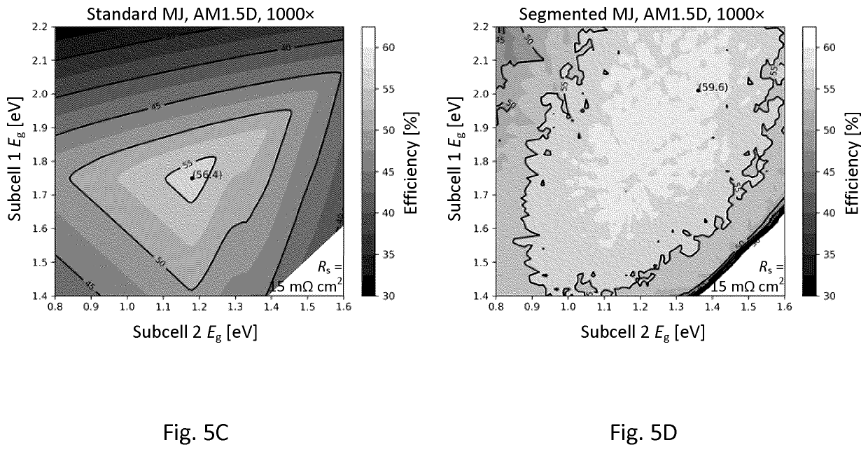

This architecture is hereinafter referred to as “Standard MJ”. The performance of these designs was computed using a current-sharing approach and was implemented in the program, EtaOpt (see G. Létay and A. W. Bett, “EtaOpt—a program for calculating limiting efficiency and optimum bandgap structure for multi-bandgap solar cells and TPV cells,” in 17th European Photovoltaic Solar Energy Conference, 2001, pp. 1-4, the relevant portions of which are incorporated by reference herein), whereby excess photons from a subcell with a large-bandgap are shared with subcells having a smaller bandgap. As will be appreciated, this approach conceptually implements the effect of having an optically thin subcell, allowing partial transmission to layers below, as needed for each combination of bandgaps to optimize the matched current. The solar-to-electrical efficiency of the Standard MJ is shown in FIG. 5A, under the illumination of an ASTM AM1.5D spectrum with 1000 suns intensity, emulating conditions within a concentrator photovoltaic system.

The Standard MJ was compared to a segmented triple-junction solar cell (hereinafter referred to as “Segmented MJ”), wherein each of the three subcells were separated into 1 to 10 segments. The number of segments in each subcell was chosen independently, and sought to maximize the usage of all photons in the absorption bands of the respective subcells. No current sharing (i.e. optical thinning) was implemented, thereby ensuring that each photon was absorbed in the subcell that most optimally utilizes the available photon energy (i.e. in the subcell with the largest bandgap that is smaller than the photon energy). The solar-to-electrical efficiency of the Segmented MJ is shown in FIG. 5B.

FIGS. 5C and FIG. 5D compare the Standard MJ to the Segmented MJ when a 15 m Ω cm² series resistance is added to the circuit. As will be appreciated, 15 m Ω cm² series resistance emulates a realistically-achievable series resistance for these types of devices.

As can be seen, over the subcell bandgap design space shown in FIGS. 5C and FIG. 5D, two very important differences are identified. First, the maximum efficiencies for the Standard MJ and Segmented MJ triple-junction designs are 56.4% (1.75, 1.18, 0.7 eV) and 59.6% (2.01, 1.36, 0.7 eV), respectively. The Segmented MJ shows an increase of 3.2% (absolute) efficiency over the Standard MJ. Second, the Segmented MJ exhibits a significantly broadened design space over which to achieve the highest efficiencies. For example, for a minimum performance of 55% efficiency, the Standard MJ achieves this minimum over less than 2% of the subcell combinations. The Segmented MJ achieves the minimum performance of 55% efficiency over 65% of the subcell design space.

In summary, FIGS. 5A to 5D show solar-to-electrical conversion efficiencies of a more general “Standard MJ” case with a structure of the form (FIG. 5A), Subcell 1 (1.4-2.2 eV)/Subcell 2 (0.8-1.6 eV)/Subcell 3 (fixed at 0.7 eV, corresponding to Ge); and a “Segmented MJ” case with an identical range of subcell bandgaps (FIG. 5B). FIG. 5C and FIG. 5D show the same, with added series resistance of Rₛ=15 m Ω cm² as an example of a more realistic device performance. Current-voltage behavior and resulting efficiency was computed under an AM1.5D spectrum with illumination intensity of 1000 suns.

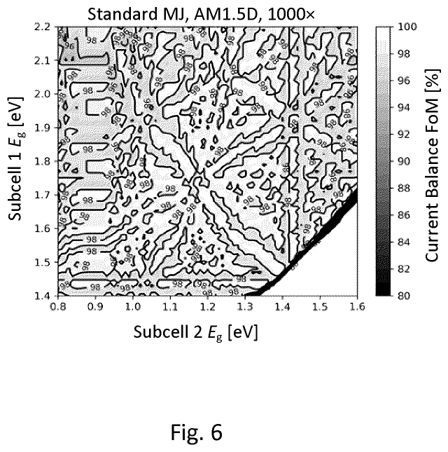

During optimization of the number of segments per subcell in each bandgap combination, a current-balance figure-of-merit was calculated to determine how effectively each photon is utilized within the absorption region of each bandgap. FIG. 6 shows a current-balance figure-of-merit, indicating how effectively all photons are used within the Segmented MJ for each combination of subcells. As will be appreciated, each point in FIG. 6 has an independently optimized number of segments in each of the three subcells, up to a maximum of ten (10) in each subcell.

By freely adjusting the number of segments, the figure-of-merit is closed to the ideal of 100%. Devices in which the maximum number of segments are limited to a smaller value would have a somewhat reduced figure-of-merit, while a higher maximum number of segments could achieve an even more ideal utilization of all photons.

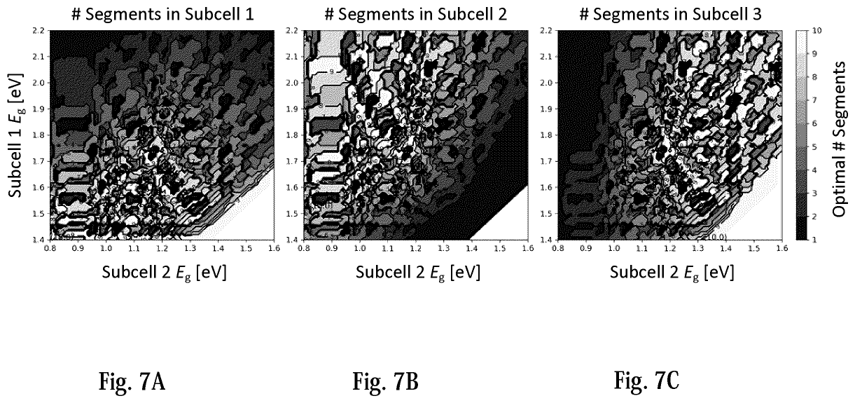

To achieve the results shown in FIG. 6, each subcell has an independently optimized number of segments to maximize the current-balance between subcells and all segments. Corresponding to the above data in FIG. 5B, FIG. 5D and FIG. 6, the numbers of segments are shown in FIGS. 7A to 7C, respectively. As such, FIGS. 7A to 7C show the number of segments in each of the optimized subcells to obtain the best current-balance figure-of-merit possible with a maximum of 10 segments in each subcell.

For the results presented herein, a maximum number of 10 segments per subcell was chosen because it was deemed a realistic number that could be achieved in the near-term. Published journal articles evaluate monochromatic phototransducers with up to 20 series-connected segments, experimental attempts have reached even higher numbers, and simulations have indicated many more should be technically achievable (see S. Fafard et al., “High-photovoltage GaAs vertical epitaxial monolithic heterostructures with 20 thin p/n junctions and a conversion efficiency of 60%,” Appl. Phys. Lett., vol. 109, no. 13, p. 131107, 2016, the relevant portions of which are incorporated herein by reference).

Although not shown, these calculations were extended to multi-junction cells having a third subcell whose bandgap is also varied. Further, any number of subcells, including two (2) or more were analyzed using a similar approach. While the analysis shown in Example 1 was limited to consideration of up to a maximum of 10 segments per subcell, it will be appreciated that the more general case includes a maximum of any number of segments, and may easily be computed using a different maximum number for each of the subcells.

### Example 2: Detailed Balance-Based Calculations of Idealized Triple-Junction Solar Cells on InP Substrate

Detailed balance-based calculations, using an approach similar to Example 1, were performed on idealized triple-junction solar cells, based on a modified design of materials and subcells on an InP substrate, assuming a bottom subcell bandgap of 0.74 eV, corresponding to lattice-matched InGaAs, as an example. This architecture is hereinafter referred to as a “Standard InP MJ”.

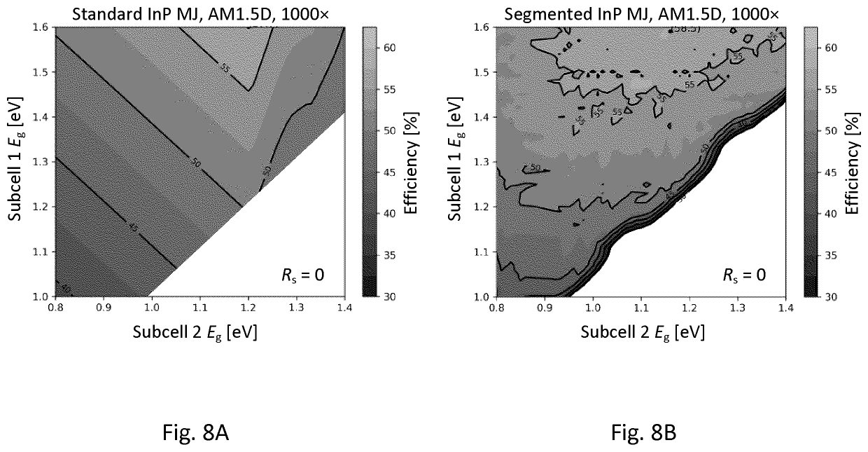

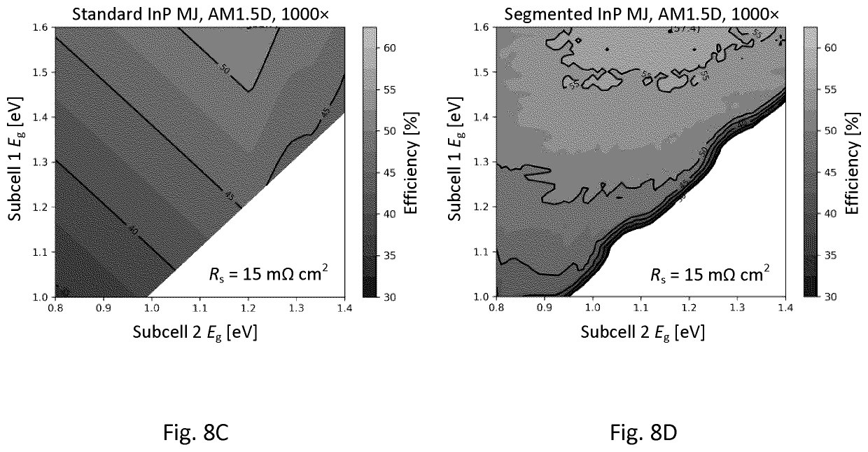

The Standard InP MJ was compared to a segmented triple-junction solar cell (hereinafter referred to as “Segmented InP MJ”), wherein each of the three subcells were separated into 1 to 10 segments. The solar-to-electrical efficiency of the Standard InP MJ is shown in FIG. 8A, under the illumination of an ASTM AM1.5D spectrum with 1000 suns intensity, emulating conditions within a concentrator photovoltaic system. The solar-to-electrical efficiency of the Segmented InP MJ is shown in FIG. 8B, under the illumination of an ASTM AM1.5D spectrum with 1000 suns intensity, emulating conditions within a concentrator photovoltaic system.

FIGS. 8C and 8D compare the Standard InP MJ to the Segmented InP MJ when a 15 m Ω cm² series resistance is added to the circuit. As will be appreciated, 15 m Ω cm² series resistance emulates a realistically-achievable series resistance for these types of devices.

As can be seen, over the subcell bandgap design space shown in FIGS. 8C and 8D, two very important differences are identified. First, the maximum efficiencies for the Standard InP MJ and Segmented InP MJ triple-junction designs are 50.3% (1.47, 1.2, 0.74 eV) and 55.7% (1.47, 1.17, 0.74 eV), respectively, where the top bandgap has been limited to ≤1.47 eV for a lattice-matched design employing commonly-used compound semiconductors. The Segmented InP MJ shows an increase of 5.4% (absolute) over the Standard InP MJ. Second, the Segmented InP MJ exhibits a significantly broadened design space over which to achieve the highest efficiencies. For example, for a minimum performance of 50% efficiency, the Standard InP MJ design achieves this minimum over 4.5% of the subcell combinations (FIG. 8C). The Segmented InP MJ achieves the minimum efficiency over 51% of the subcell design space

### Example 3: Detailed Balance-Based Calculations of Idealized Triple-Junction Solar Cells in Outer Space

Detailed balance-based calculations, using an approach similar to Example 1, were performed on idealized triple-junction solar cells on a Ge substrate, assuming a bottom subcell bandgap of 0.7 eV, as an example. This architecture is hereinafter referred to as a “Standard Ge MJ” below.

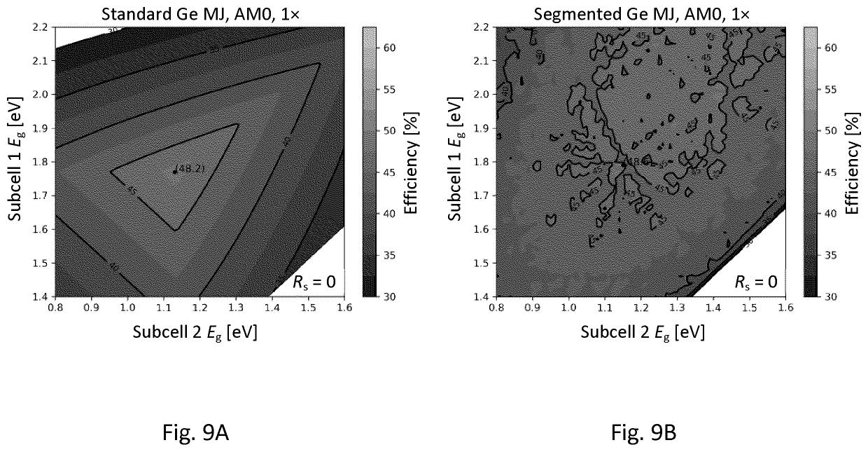

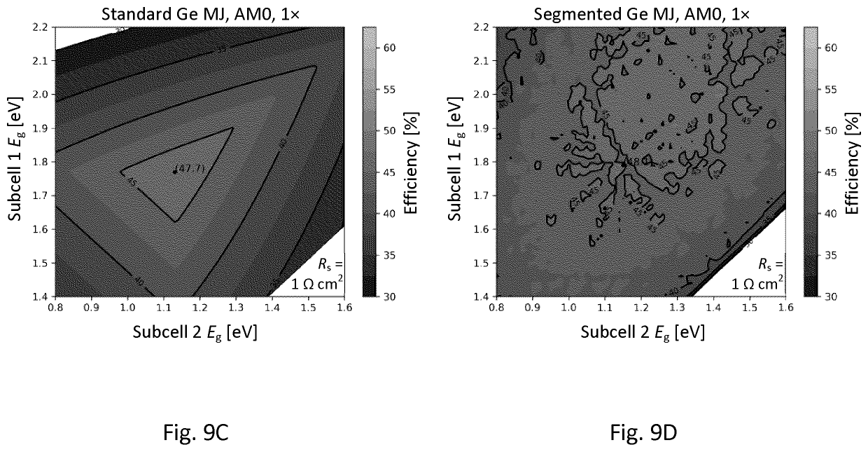

The Standard Ge MJ was compared to a segmented triple-junction solar cell (hereinafter referred to as “Segmented Ge MJ”), wherein each of the three subcells were separated into 1 to 10 segments. The solar-to-electrical efficiency of the Standard Ge MJ is shown in FIG. 9A, under the illumination of an AMO extraterrestrial spectrum without solar concentration, emulating conditions outside Earth's atmosphere. The solar-to-electrical efficiency of the Segmented Ge MJ is shown in FIG. 9B, under the illumination of an AMO extraterrestrial spectrum without solar concentration, emulating conditions outside Earth's atmosphere.

FIGS. 9C and 9D compare the Standard Ge MJ to the Segmented Ge MJ when a 1Ω cm² series resistance is added to the circuit. As will be appreciated, 1Ω cm² series resistance emulates a realistically-achievable series resistance for these types of devices.

As can be seen, over the subcell bandgap design space shown in FIGS. 9C and 9D, two very important differences can be identified. First, the maximum efficiencies for the Standard Ge MJ and the Segmented Ge MJ triple-junction designs are 45.1% (1.9, 1.29, 0.7 eV) and 47.5% (1.9, 1.29, 0.7 eV), respectively, where the top bandgap has been set to a realizable value of 1.9 eV corresponding to lattice-matched disordered InGaP. For the special case of (1.9, 1.4, 0.7 eV) design, the efficiencies for the Standard Ge MJ and the Segmented Ge MJ triple-junction designs are 41.6% and 45.4%, respectively. The Segmented Ge MJ design shows an increase of 2.4% and 3.8% (absolute) under those two scenarios. Second, the Segmented Ge MJ design exhibits a significantly broadened design space over which to achieve the highest of efficiencies. For example, choosing a minimum performance of 45% efficiency, the Standard Ge MJ design achieves this minimum over <6% of the subcell combinations (FIG. 9C). The Segmented Ge MJ achieves the minimum efficiency over 27% of the subcell design space (FIG. 9D).

While the above calculations were completed using the AM1.5D or AM0 standard solar spectra, many analyses such as energy yield calculations would necessarily require additional calculations under alternative solar spectra (for instance, variation in air mass, aerosol optical depth, precipitable water, ozone, particulates, etc.). This analysis would be equally valid under any general spectra, including other natural and artificial light sources.

### Clauses

Clause 1. A photovoltaic device comprising: at least two sub-cells, at least one connecting element electrically connecting adjacent sub-cells to one another, each sub-cell comprising: at least one segment; and at least one connecting element electrically connecting adjacent segments to one another in the event that a sub-cell has more than one segment; each one of the sub-cells having a unique bandgap and being arranged such that bandgaps of the sub-cells are in descending order with respect to a light incident surface of the photovoltaic device, each sub-cell being designed such that all segments of the photovoltaic device produce approximately the same current.

Clause 2. The photovoltaic device of Clause 1 wherein each segment comprises at least one emitter and base.

Clause 3. The photovoltaic device of Clause 2 wherein the emitter is one of p-doped and n-doped and the base is the other of p-doped and n-doped.

Clause 4. The photovoltaic device of any one of Clauses 1 to 3 wherein a first sub-cell comprises four segments.

Clause 5. The photovoltaic device of Clause 4 wherein a second sub-cell comprises three segments.

Clause 6. The photovoltaic device of any one of Clauses 1 to 5 wherein one of the sub-cells is made of indium gallium phosphide (InGaP) and has a bandgap of approximately 1.8 eV.

Clause 7. The photovoltaic device of any one of Clauses 1 to 6 wherein one of the sub-cells is made of gallium arsenide (GaAs) and has a bandgap of approximately 1.4 eV.

Clause 8. The photovoltaic device of any one of Clauses 1 to 7 wherein the at least one connecting element electrically connecting adjacent sub-cells to one another is made of a material substantially transparent to light being absorbed by a lower of the adjacent sub-cells with respect to the light incident surface.

Clause 9. The photovoltaic device of any one of Clauses 1 to 8 further comprising a layer configured to extract current and voltage from the photovoltaic device.

Clause 10. The photovoltaic device of any one of Clauses 1 to 9 further comprising the light incident surface.

Clause 11. The photovoltaic device of any one of Clauses 1 to 10 wherein the at least one connecting element electrically connecting adjacent segments to one another comprises at least one highly n-doped layer and at least one highly p-doped layer.

Clause 12. The photovoltaic device of Clause 11 wherein each segment of at least one of the sub-cells have generally the same voltage.

Clause 13. The photovoltaic device of any one of Clauses 1 to 12, wherein the at least one connecting element electrically connecting adjacent sub-cells to one another is a tunnel junction.

Clause 14. The photovoltaic device of any one of Clauses 1 to 13 wherein the at least one connecting element electrically connecting adjacent segments to one another is a tunnel junction.

Clause 15. The photovoltaic device of any one of Clauses 1 to 14, wherein the photovoltaic device is a solar cell.

Clause 16. The photovoltaic device of any one of Clauses 1 to 15, wherein the photovoltaic device is formed by epitaxial growth in a single monolithic stack.

Clause 17. The photovoltaic device of Clause16, wherein the single monolithic stack is comprised entirely of layers that are lattice-matched to a substrate of the photovoltaic device.

Clause 18. The photovoltaic device of Clause 16, wherein the single monolithic stack comprises at least one layer that is lattice-mismatched to a substrate of the photovoltaic device.

Clause 19. The photovoltaic device of any one of Clauses 1 to 15, wherein the photovoltaic device is composed of a wafer-bonded stack of two or more sub-devices, each separately formed by epitaxial growth in a monolithic stack.

Clause 20. The photovoltaic device of any one of Clauses 1 to 15, wherein the photovoltaic device is composed of a wafer-bonded stack of two or more sub-devices each separately formed by epitaxial growth in a monolithic stack, wherein at least one of the sub-devices is comprised entirely of layers that are lattice-matched to a substrate of the photovoltaic device and the remaining sub-devices comprise at least one layer that is lattice-mismatched to the substrate.

Clause 21. The photovoltaic device of any one of Clauses 1 to 15, wherein the photovoltaic device is composed of mechanical stacking of two or more sub-devices.

Clause 22. The photovoltaic device of any one of Clauses 1 to 15, wherein the photovoltaic device is composed of two or more sub-devices stacked via combinations of wafer-bonding and mechanical stacking.

Clause 23. The photovoltaic device of any one of Clauses 1 to 15, wherein the photovoltaic device is composed of a mechanical stack of two or more sub-devices, each separately formed by at least one of epitaxial growth in a monolithic stack and wafer bonding.

Clause 24. The photovoltaic device of any one of Clauses 1 to 23 further comprising one or more monolithic stacks formed via one or more thin film deposition techniques selected from a group consisting of thermal evaporation, electron-beam evaporation, sputtering, atomic layer deposition, pulsed laser deposition, cathodic arc deposition, electrodeposition, electrohydrodynamic deposition, sol-gel method, dip coating, spin coating, spraying techniques, chemical vapor deposition, plasma enhanced chemical vapor deposition, metalorganic chemical vapor deposition, plasma enhance chemical vapor deposition, molecular beam epitaxy, and chemical beam epitaxy.

Although embodiments have been described above with reference to the accompanying drawings, those of skill in the art will appreciate that variations and modifications may be made without departing from the scope thereof as defined by the appended claims.

1. A photovoltaic device comprising:
at least two sub-cells, at least one connecting element electrically connecting adjacent sub-cells to one another, each sub-cell comprising:
at least one segment; and
at least one connecting element electrically connecting adjacent segments to one another in the event that a sub-cell has more than one segment;
each one of the sub-cells having a unique bandgap and being arranged such that bandgaps of the sub-cells are in descending order with respect to a light incident surface of the photovoltaic device, each sub-cell being designed such that all segments of the photovoltaic device produce approximately the same current.

2. The photovoltaic device of claim 1 wherein each segment comprises at least one emitter and base.

3. The photovoltaic device of claim 2 wherein the emitter is one of p-doped and n-doped and the base is the other of p-doped and n-doped.

4. The photovoltaic device of claim 1 wherein a first sub-cell comprises four segments.

5. The photovoltaic device of claim 4 wherein a second sub-cell comprises three segments.

6. The photovoltaic device of claim 1 wherein one of the sub-cells is made of indium gallium phosphide (InGaP) and has a bandgap of approximately 1.8 eV.

7. The photovoltaic device of claim 1 wherein one of the sub-cells is made of gallium arsenide (GaAs) and has a bandgap of approximately 1.4 eV.

8. The photovoltaic device of claim 1 wherein the at least one connecting element electrically connecting adjacent sub-cells to one another is made of a material substantially transparent to light being absorbed by a lower of the adjacent sub-cells with respect to the light incident surface.

9. The photovoltaic device of claim 1 further comprising a layer configured to extract current and voltage from the photovoltaic device.

10. The photovoltaic device of claim 1 further comprising the light incident surface.

11. The photovoltaic device of claim 1 wherein the at least one connecting element electrically connecting adjacent segments to one another comprises at least one highly n-doped layer and at least one highly p-doped layer.

12. The photovoltaic device of claim 11 wherein each segment of at least one of the sub-cells have generally the same voltage.

13. The photovoltaic device of claim 1 wherein the at least one connecting element electrically connecting adjacent sub-cells to one another is a tunnel junction.

14. The photovoltaic device of claim 1 wherein the at least one connecting element electrically connecting adjacent segments to one another is a tunnel junction.

15. The photovoltaic device of claim 1 wherein the photovoltaic device is a solar cell.

16. The photovoltaic device of claim 1 wherein the photovoltaic device is formed by epitaxial growth in a single monolithic stack.

17. The photovoltaic device of claim 16, wherein the single monolithic stack (i) is comprised entirely of layers that are lattice-matched to a substrate of the photovoltaic device or (ii) comprises at least one layer that is lattice-mismatched to a substrate of the photovoltaic device.

18. (canceled)

19. The photovoltaic device of claim 1 wherein the photovoltaic device (i) is composed of a wafer-bonded stack of two or more sub-devices, each separately formed by epitaxial growth in a monolithic stack or (ii) is composed of a wafer-bonded stack of two or more sub-devices each separately formed by epitaxial growth in a monolithic stack, wherein at least one of the sub-devices is comprised entirely of layers that are lattice-matched to a substrate of the photovoltaic device and the remaining sub-devices comprise at least one layer that is lattice-mismatched to the substrate.

20. (canceled)

21. The photovoltaic device of claim 1 wherein the photovoltaic device (i) is composed of mechanical stacking of two or more sub-devices, (ii) is composed of two or more sub-devices stacked via combinations of wafer-bonding and mechanical stacking or (iii) is composed of a mechanical stack of two or more sub-devices, each separately formed by at least one of epitaxial growth in a monolithic stack and wafer bonding.

22. (canceled)

23. (canceled)

24. The photovoltaic device of claim 1 further comprising one or more monolithic stacks formed via one or more thin film deposition techniques selected from a group consisting of thermal evaporation, electron-beam evaporation, sputtering, atomic layer deposition, pulsed laser deposition, cathodic arc deposition, electrodeposition, electrohydrodynamic deposition, sol-gel method, dip coating, spin coating, spraying techniques, chemical vapor deposition, plasma enhanced chemical vapor deposition, metalorganic chemical vapor deposition, plasma enhance chemical vapor deposition, molecular beam epitaxy, and chemical beam epitaxy.
